(19) United States
(12) Patent Application Publication
(10) Pub. No.: US 2026/0190836 A1
(43) Pub. Date: Jul. 2, 2026

(54) Transparent Display Device

(71) Applicant: LG Display Co, Ltd., Seoul (KR)

(72) Inventor: In Tae Ko, Paju-si (KR)

(21) Appl. No.: 19/427,807

(22) Filed: Dec. 19, 2025

(30) Foreign Application Priority Data
Dec. 30, 2024 (KR) 10-2024-0200859

(51) Int. Cl. H10K 59/80; H10K 59/122; H10K 59/131; H10K 59/40

(52) U.S. Cl. CPC H10K 59/8792; H10K 59/122; H10K 59/131; H10K 59/873; H10K 59/40

(57) ABSTRACT

A transparent display device includes a substrate having a plurality of emission areas and a plurality of transparent areas spaced apart from each other, a light-emitting element at the emission areas, an encapsulation layer on the light-emitting elements, a first wiring layer and a second wiring layer disposed on the encapsulation layer and positioned at different layers, a touch buffer layer between the encapsulation layer and the first wiring layer, a touch intermediate insulating layer disposed between the first wiring layer and the second wiring layer, a first protective layer on the second wiring layer, an external light reflection prevention layer disposed on the first protective layer and including a light-shielding layer and a color filter layer and a second protective layer disposed on the external light reflection prevention layer at the plurality of emission areas and on the encapsulation layer at the plurality of transparent areas.

### CROSS-REFERENCE TO RELATED APPLICATIONS

This application claims the benefit of Korean Patent Application No. 10-2024-0200859, filed on Dec. 30, 2024, which is hereby incorporated by reference as if fully set forth herein.

### BACKGROUND OF THE DISCLOSURE

### Field of the Disclosure

The present disclosure relates to a display device, and more specifically, to a transparent display device having improved transmittance and purity.

### Discussion of the Related Art

Display devices that display images on TVs, monitors, smartphones, tablets, and laptops are being used in various methods and forms.

These display devices do not require a separate light source, and compactness of devices and clear color display are required. Accordingly, self-luminous display devices such as organic light-emitting display devices and quantum dot light-emitting display devices are being considered as competitive applications.

A self-luminous display device has a plurality of pixels on a substrate and includes a light-emitting diode having two electrodes facing each other and an emission layer therebetween in each pixel.

Recently, application of such self-luminous display devices to transparent display devices capable of emission and transparent display simultaneously is being considered.

### SUMMARY OF THE DISCLOSURE

Accordingly, the present disclosure is directed to a transparent display device that substantially obviates one or more problems due to limitations and disadvantages of the related art.

An aspect of the present disclosure is to provide a transparent display device having an additional functional unit on a light-emitting element, which can prevent or minimize interfacial reflection within a transparent area.

An aspect of the present disclosure is to provide a transparent display device having improved transmittance.

An aspect of the embodiments of the present disclosure is to provide a transparent display device having improved purity.

An aspect of the present disclosure is to provide a transparent display device having improved transmittance and purity of a transparent area by preventing refraction due to components surrounding the transparent area.

An aspect of the present disclosure is to improve transmittance and purity of a transparent display device and achieve ESG (Environmental/Social/Governance) through improved visibility.

Additional advantages, aspects, and features of the present disclosure will be set forth in part in the description which follows and in part will become apparent to those having ordinary skill in the art upon examination of the following or may be learned from practice of the present disclosure. The aspects and other advantages of the present disclosure may be realized and attained by the structure particularly pointed out in the written description and claims hereof as well as the appended drawings.

To achieve these aspects and other advantages and in accordance with the purpose of the present disclosure, as embodied and broadly described herein, a transparent display device according to an aspect of the present disclosure includes a substrate having a plurality of emission areas and a plurality of transparent areas spaced apart from each other, a light-emitting element at the emission areas, an encapsulation layer on the light-emitting elements, a first wiring layer and a second wiring layer disposed on the encapsulation layer and positioned at different layers, a touch buffer layer between the encapsulation layer and the first wiring layer, a touch intermediate insulating layer disposed between the first wiring layer and the second wiring layer, a first protective layer on the second wiring layer, an external light reflection prevention layer disposed on the first protective layer and including a light-shielding layer and a color filter layer and a second protective layer disposed on the external light reflection prevention layer at the plurality of emission areas and on the encapsulation layer at the plurality of transparent areas.

It is to be understood that both the foregoing general description and the following detailed description of the present disclosure are exemplary and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a plan view showing a transparent display device according to an embodiment of the present disclosure;

FIG. 2 is a circuit diagram of a subpixel provided at the intersection of a gate line and a data line of FIG. 1;

FIG. 3 is an enlarged view of area A in FIG. 1;

FIG. 4 is a cross-sectional view taken along line I-I′ in FIG. 3;

FIG. 5 is a cross-sectional view taken along line II-II′ in FIG. 3;

FIG. 6A and FIG. 6B are diagrams showing interfacial reflection phenomena of first and second experimental examples;

FIG. 7 to FIG. 9 are cross-sectional views taken along line II-II′ in FIG. 3 according to other embodiments; and

FIG. 10A and FIG. 10B are photographs showing images before and after removal of an inorganic insulating layer of a transparent area.

### DETAILED DESCRIPTION OF THE DISCLOSURE

Hereinafter, embodiments of the present disclosure will be described with reference to the attached drawings.

The same or extremely similar elements are designated by the same reference numerals throughout the specification, and in the drawings, the lengths and thickness of layers and regions may be exaggerated for convenience. The scale of the components shown in the drawings is different from the actual scale, and is not limited to the scale shown in the drawings.

It will be understood that, when a certain element (or a region, a layer, or a portion) is referred to as being “on”, “connected to” or “combined with” another element, the element may be directly connected/combined to/with the other element, or a third element may be interposed therebetween.

“And/or” includes any combination of one or more of the associated components.

While terms, such as “first”, “second”, etc., may be used to describe various components, such components must not be limited by the above terms. The above terms are used only to distinguish one component from another. In addition, terms particularly defined in consideration of construction and operation of the embodiments are used only to describe the embodiments and do not define the scope of the embodiments.

In the description of the embodiments, it will be understood that, when an element is referred to as being formed “on” or “under” another element, it can be directly “on” or “under” the other element or be indirectly formed with intervening elements therebetween. It will also be understood that, when an element is referred to as being “on” or “under”, “under the element” as well as “on the element” can be included based on the element.

It will be further understood that the terms “comprise” and “include” specify the presence of stated features, integers, steps, operations, elements, components, and/or combinations thereof, but do not preclude the presence or addition of one or more other features, integers, steps, operations, elements, components, and/or combinations.

The respective features of the various embodiments of the present disclosure may be partially or wholly coupled to and combined with each other, and various technical linkage and driving thereof are possible. These various embodiments may be performed independently of each other, or may be performed in association with each other.

Hereinafter, a transparent display device of the present disclosure will be described with reference to the attached drawings and embodiments.

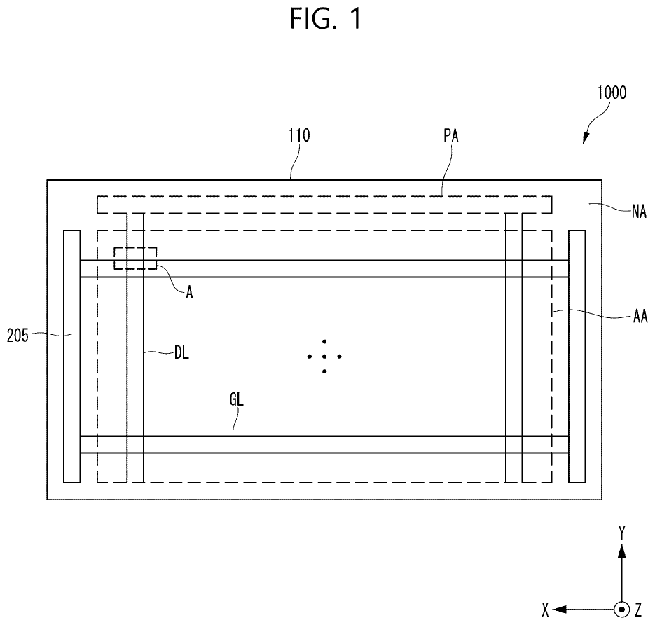

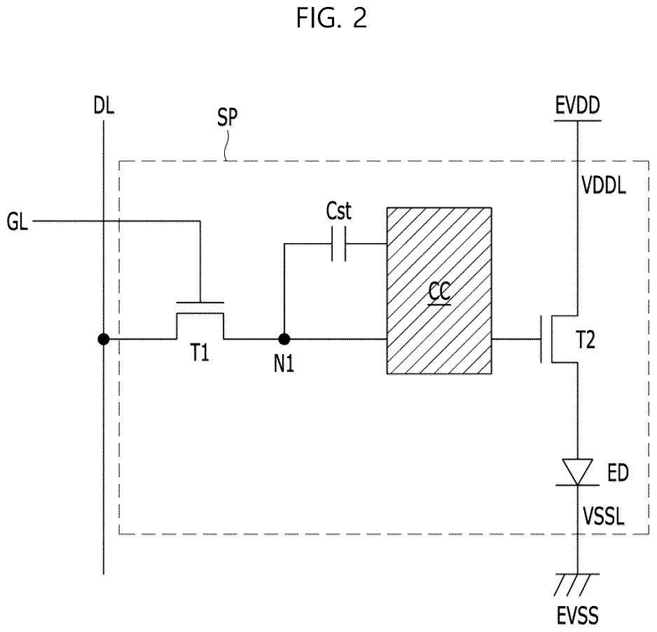

FIG. 1 is a plan view showing a transparent display device according to an embodiment of the present disclosure. FIG. 2 is a circuit diagram of a subpixel provided at an intersection of a gate line and a data line of FIG. 1.

Referring to FIG. 1 and FIG. 2, a transparent display device 1000 according to an embodiment of the present disclosure includes a display panel 110 including a substrate 100 having an active area AA and a non-active area NA surrounding the active area AA, a plurality of gate lines GL and a plurality of data lines DL intersecting each other on the substrate 100, subpixels SP disposed between the gate lines GL and the data lines DL, a gate driver 205 disposed in the non-active area NA and supplying a gate voltage signal to the gate lines GL, and a pad PA disposed in the non-active area NA and used to supply an image signal to the data lines DL.

The non-active area NA may be covered by a case or by a separate light-blocking layer. The case may be provided on at least a portion of the side and bottom of the display panel 110. A printed circuit layer and/or a battery may be provided between the lower portion of the display panel DP and the case.

The active area AA is an area for displaying an image. A plurality of subpixels SP is disposed in the active area AA, and an image can be displayed using the plurality of subpixels SP. The non-active area NA is an area other than the active area AA.

The non-active area NA may be disposed in an edge area surrounding the active area AA for displaying an image. At least one driver for driving the plurality of subpixels SP may be disposed in the non-active area NA. The driver may include a gate-in-panel (GIP) provided together with the components of transistors T1 and T2 included in the subpixels in the same stack. The gate driver 205 of FIG. 1 takes a GIP structure and may be connected to a plurality of gate lines GL of the active area AA to sequentially supply gate voltage signals to the plurality of gate lines GL.

Various additional elements for driving the subpixels SP within the active area AA may be further disposed in the non-active area NA.

At least one of the plurality of subpixels may include, for example, a first transistor T1, a second transistor T2, a storage capacitor Cst, a compensation circuit CC, and a light-emitting element ED, as shown in FIG. 2.

For example, the first transistor T1 may be a switching transistor and the second transistor T2 may be a driving transistor.

A first electrode (e.g., a drain electrode) of the first transistor T1 is electrically connected to a data line DL, and a second electrode (e.g., a source electrode) thereof is electrically connected to a first node N1. A gate electrode of the first transistor T1 is electrically connected to a gate line GL. The first transistor T1 transmits a data signal supplied through the data line DL to the first node N1 in response to a scan signal supplied through the gate line GL.

The storage capacitor Cst is electrically connected to the first node N1 and is charged by the voltage applied to the first node N1.

A first electrode (e.g., a drain electrode) of the second transistor T2 receives a high-level voltage EVDD, and a second electrode (e.g., a source electrode) thereof is electrically connected to a first electrode (e.g., an anode) of the light-emitting element ED. The second transistor T2 may control the amount of driving current flowing through the light-emitting element ED according to a voltage difference between the gate electrode and the source electrode.

A semiconductor layer of at least one of the first transistor T1 or the second transistor T2 may include silicon such as amorphous silicon (a-Si), polycrystalline silicon (poly-Si), or low-temperature polycrystalline silicon (poly-Si), or may include an oxide semiconductor.

The transistors and display devices of the embodiments of the present disclosure may have the advantage of including an oxide semiconductor layer in at least one of the transistors formed on the substrate 111, enabling formation at a relatively low temperature compared to other semiconductor materials, maintaining stabilized off characteristics, and having high mobility during operation.

The light-emitting element ED emits light corresponding to the driving current. One side of the light-emitting element ED is connected to the second transistor T2 and the other side thereof is connected to a first power voltage line VSSL through which a ground voltage or a low-level voltage EVSS is supplied, and the light-emitting element ED may emit light corresponding to one of red, green, blue, and white in each subpixel. The ground voltage or low-level voltage EVSS may be commonly supplied into a second electrode of the light-emitting element ED over an entire area of the active area AA.

The light-emitting element ED may include a first electrode, an intermediate layer disposed on the first electrode, and a second electrode. The intermediate layer may include at least one emission layer, and may be implemented to emit light of the same color for each subpixel, such as white light, or may be implemented to emit different colors for subpixels (SP), such as red, green, or blue light when an electric field is formed between the first electrode and the second electrode. In addition to the emission layer, the intermediate layer may include various types of common layers and functional layers to efficiently supply holes and electrons to the emission layer. The second electrode may be directly or indirectly connected to the first power voltage line VSSL to which the low-level voltage EVSS or the ground voltage is supplied. The first power voltage line to which the low-level voltage EVSS or the ground voltage is supplied may be provided in the non-active area NA and additionally provided to be connected to at least one subpixel SP in the active area AA. The second transistor T2 that supplies the driving current is connected to a second power voltage line VDDL on the side that is not connected to the light-emitting element ED, and a high-level voltage EVDD may be supplied to the second transistor T2.

The compensation circuit CC may be additionally provided in the subpixel SP to compensate for the threshold voltage of the second transistor T2. The compensation circuit CC may be composed of one or more transistors. The compensation circuit CC may include one or more transistors and capacitors, and may be configured in various manners depending on the compensation method. The subpixel SP including the compensation circuit CC may include circuits of various structures having different numbers of transistors and/or capacitors, such as 3T1C, 4T2C, 5T2C, 6T1C, 6T2C, 7T1C, and 7T2C.

Among the transistors provided in the subpixel, the switching transistor may require high-speed driving for fast switching operation. The driving transistor may be required to output a high current in order to supply the high current to the light-emitting element to achieve high luminance.

The gate driver 205 taking a GIP structure provided in the non-active area NA outputs gate signals to gate lines according to a gate control signal input from a timing controller, for example. The gate driver 205 may include a plurality of transistors, and the plurality of transistors may be formed through the same process as the process for forming the transistors of the subpixel SP.

The display device of the embodiments of the present disclosure has a transparent area along with an emission area within the active area AA, thereby increasing transmittance and improving purity. The specific structure will be described with reference to the drawings below.

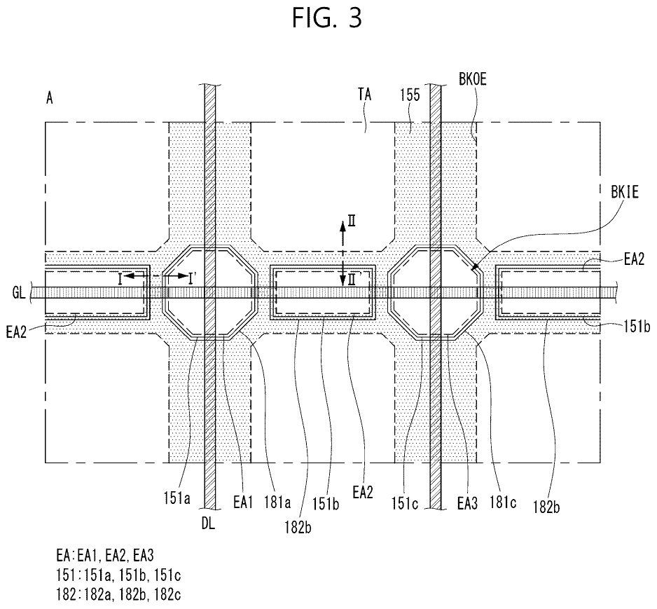

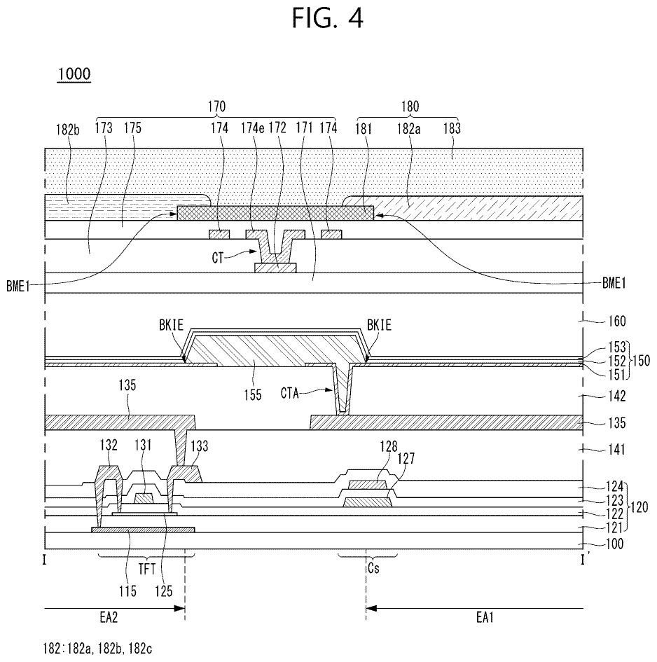

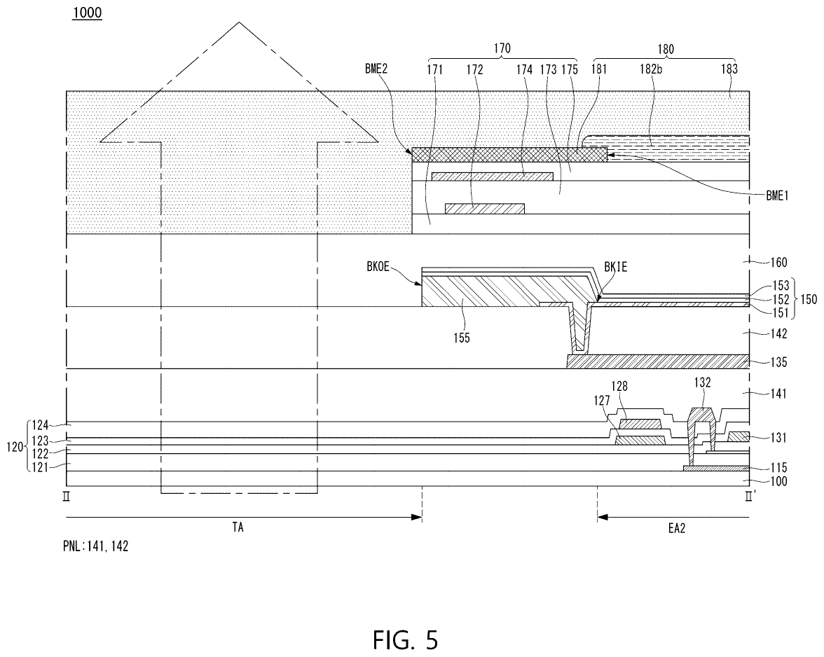

FIG. 3 is an enlarged view of area A in FIG. 1, and FIG. 4 is a cross-sectional view taken along line I-I′ in FIG. 3. FIG. 5 is a cross-sectional view taken along line II-II′ in FIG. 3.

As shown in FIG. 3 to FIG. 5, the transparent display device 1000 according to an embodiment of the present disclosure may include a substrate 100 having a plurality of emission areas EA (EA1, EA2, and EA3) and a plurality of transparent areas TA spaced apart from each other, a light-emitting element 150 provided on the substrate, an encapsulation layer 160 disposed on the light-emitting element 150, a touch sensor 170 disposed on the encapsulation layer 160 and including at least a first wiring layer 172 and a second wiring layer 174 positioned in different layers, and an external light reflection prevention layer 180 including a light-shielding layer 181 and a color filter 182 (182a, 182b, and 182c) on the touch sensor 170.

Here, the touch sensor 170 includes a touch buffer layer 171 positioned between the encapsulation layer 160 and the first wiring layer 172, a touch intermediate insulating layer 173 positioned between the first wiring layer 172 and the second wiring layer 174, and a first protective layer 175 positioned on the second wiring layer 174.

All of the insulating layers included in the touch sensor 170 are transparent insulating layers.

In addition, the insulating layers included in the touch sensor 170 are relatively thin compared to a second protective layer 183 positioned at the top of the transparent display device 1000 and may be provided for insulation and interference prevention of upper and lower components.

Each of the insulating layers included in the touch sensor 170 may be an inorganic insulating layer. Examples of the inorganic insulating layer may include a silicon nitride layer, a silicon oxide layer, and a silicon oxynitride layer.

The touch buffer layer 171, the touch intermediate insulating layer 173, and the first protective layer 175 may be made of a material having a refractive index of 1.6 or higher.

In the transparent display device 1000 of an embodiment of the present disclosure, the touch buffer layer 171, the touch intermediate insulating layer 173, and the first protective layer 175 may be removed from the transparent area TA to remove a component reflected at the interface of thin inorganic insulating layers of the transparent area TA on the encapsulation layer 160. Therefore, the purity of the transparent area TA can be improved.

The encapsulation layer 160 of the transparent area TA is thicker than the inorganic insulating layers 171, 173, and 175 of the touch sensor 170, and thus interfacial reflection caused by the encapsulation layer 160 hardly occurs. In addition, since the encapsulation layer 160 and the second protective layer 183 having similar refractive indices meet in the transparent area TA, refraction or interfacial reflection hardly occurs in the encapsulation layer 160 and the second protective layer 183 having a small refractive index difference therebetween.

Here, in the transparent area TA, the second protective layer 183 may contact the upper surface of the encapsulation layer 160.

The encapsulation layer 160 is disposed on the light-emitting element 150 to protect the light-emitting element 150, and is disposed with an area larger than each of the first electrode 151, the intermediate layer 152, and the second electrode 153 of the light-emitting element 150.

Since the touch buffer layer 171, the touch intermediate insulating layer 173, and the first protective layer 175 have removed portions in the transparent area TA, each of the touch buffer layer 171, the touch intermediate insulating layer 173, and the first protective layer 175 may have a side surface around the transparent area TA.

The touch buffer layer 171, the touch intermediate insulating layer 173, and the first protective layer 175 may be independently disposed non-overlapping manner in a plurality of transparent areas TA. In some cases, some of the touch buffer layer 171, the touch intermediate insulating layer 173, and the first protective layer 175 may remain in the transparent area TA.

The touch buffer layer 171, the touch intermediate insulating layer 173, and the first protective layer 175 may each be an inorganic insulating layer.

The refractive index of each of the touch buffer layer 171, the touch intermediate insulating layer 173, and the first protective layer 175 may be greater than the refractive index of the second protective layer 183.

Since the touch buffer layer 171, the touch intermediate insulating layer 173, and the first protective layer 175 having relatively high refractive indexes and disposed under the second protective layer 183 are removed in the transparent area TA, interfacial reflection occurring when a low refractive index layer and a high refractive index layer meet is prevented, and thus the cause of reduced purity due to refraction and reflection between layers on the encapsulation layer 160 can be resolved.

The touch intermediate insulating layer 173 includes a contact hole CT, and thus a connection pattern 174e disposed on the same layer as the second wiring layer 174 can be connected to the first wiring layer 172 through the contact hole CT.

The contact hole CT of the touch intermediate insulating layer 173, the first and second wiring layers 172 and 174, and the light-shielding layer 181 are disposed not to overlap the transparent area TA, and thus the pure transmittance of the transparent area TA is not reduced.

The light-shielding layer 181 among the components disposed on the encapsulation layer 160 may have an end line relatively farther outside than the bank 155 disposed below the encapsulation layer 160. That is, a light-shielding layer end line BME1 adjacent to the emission area is closer to the emission area EA (EA1, EA2, and EA3) than a bank end line BKIE adjacent to the emission area. In addition, a light-shielding layer end line BME2 adjacent to the transparent area is closer to the transparent area TA than a bank end line BKOE adjacent to the transparent area.

Accordingly, the light-shielding layer 181 is disposed to cover the end of the bank 155 and thus can be adjacent to the emission area EA (EA1, EA2, and EA3) rather than the bank 155. The light-shielding layer 181 may also be disposed closer to the transparent area TA than the bank 155. Accordingly, the light-shielding layer 181 blocks optical abnormal paths such as refraction or fringes that occur at the end of the bank 155, and thus both the transmittance and purity of the transparent display device can be improved.

Hereinafter, the configuration of each layer will be described in detail.

The substrate 100 supports and protects components disposed thereon. The substrate 100 may be transparent and may have flexibility. The substrate 100 may be made of, for example, glass or a plastic material.

In an embodiment of the present disclosure, the substrate 100 may be formed of multiple layers, and may be formed, for example, in a form in which an interlayer inorganic layer is disposed between different flexible substrates.

In an embodiment of the present disclosure, the substrate 100 includes emission areas EA1, EA2, and EA3 and transparent areas TA spaced apart from each other, and the transparent areas TA may be arranged such that they do not overlap components including a light-blocking metal material such as wiring lines including gate lines GL, data lines DL, and transistors, thereby increasing the pure transmittance of light passing through the substrate 100. Accordingly, an object or image located under the substrate 100 can be observed from the outside of the uppermost component of the substrate 100. On the other hand, the emission areas EA1, EA2, and EA3 includes the light-emitting element (ED) 150, and may overlap wiring lines including gate lines GL and data lines DL and a transistor TFT which are components beneath the light-emitting element 150. Here, the light-emitting element 150 is formed by sequentially laminating a first electrode 151 provided for each subpixel, an intermediate layer 152, and a second electrode 153. In the emission areas EA1, EA2, and EA3, light generated inside the light-emitting element 150 is emitted from the second electrode 153, and an image according to the operation of the light-emitting element can be observed from the outside of the uppermost component of the substrate 100.

The first electrode 151 of the light-emitting element 150 includes a reflective electrode, and thus even if it overlaps with an wiring line such as a gate line GL, a data line DL, or the transistor TFT in the emission areas EA1, EA2, and EA3, the light emitted from the light-emitting element 150 is not affected by the light-shielding property of the metal included in the wiring lines such as the gate line GL and the data line DL or the transistor TFT. That is, the light emitted from the intermediate layer 152 of the light-emitting element 150 is reflected and resonated repeatedly between the first electrode 151 and the second electrode 153 and is finally emitted through the second electrode 153.

The transparent area TA removes light-shielding components from the area where light overlaps, thereby increasing the pure transmittance of light.

In the transparent display device 1000 according to an embodiment of the present disclosure, light that has traveled from the lower side of the substrate 100 through an area corresponding to the transparent area TA can pass through the second protective layer 183, which is the uppermost component of the substrate 100, and be visible to a viewer. That is, the viewer can recognize an object or an image behind the substrate 100 through the transparent display device 1000 according to an embodiment of the present disclosure.

The second protective layer 183 is made of a transparent organic insulating material and serves to protect the internal components against external contact or physical impact. In addition, the second protective layer 183 planarizes the surface and has a refractive index similar to those of the substrate 100 and the encapsulation layer 160, and thus significant interfacial reflection is not induced for light traveling in the vertical direction in the transparent area TA, and an image behind the substrate can be viewed without distortion or refraction. In the transparent area TA, the insulating layers 171, 173, and 175 included in the touch sensor 170 are all removed, thereby preventing or at least reducing interfacial reflection that may occur in the insulating layers on the encapsulation layer 160.

The organic insulating material forming the second protective layer 183 may include one or more of acrylic resin, phenolic resin, polyimide resin, unsaturated polyester resin, polyamide resin, benzocyclobutene, polyphenylene resin, and polyphenylene sulfide resin.

The illustrated transistor TFT may be one of the first and second transistors T1 and T2 illustrated in FIG. 2.

The transistor TFT provided on the substrate 100 may include, for example, an active layer 125, a gate electrode 131 overlapping the active layer 125 with a second insulating layer 122 interposed therebetween, a first source-drain electrode 132 and a second source-drain electrode 133 connected to both sides of the active layer 125. The active layer 125 may include a semiconductor material. The semiconductor material may be a silicon-based semiconductor or an oxide-based material semiconductor material.

A light-shielding pattern 115 may be further provided under the transistor TFT on the substrate 100, specifically, under the active layer 125. The light-shielding pattern 115 may block light from the lower side of the substrate 100 being transmitted to the transistor TFT, thereby preventing or at least reducing abnormalities in the active layer 125, such as photocurrent generation.

A first insulating layer 121 may be provided between the light-shielding pattern 115 and the active layer 125 on the substrate 100. The first insulating layer 121 may serve as a buffer layer. The first insulating layer 121 may have a function of preventing or at least reducing impurities included in the substrate 100 from being transferred to the active layer 125 and planarizing the surface on which the active layer 125 is formed. The first insulating layer 121 may cover the light-shielding pattern 115. The first insulating layer 121 may protect structures on the substrate 100 that are vulnerable to moisture penetration from moisture penetrating through the substrate 100 and planarize the surface of the substrate 100.

In some cases, one or more insulating layers may be provided between the light-shielding pattern 115 and the substrate 100 to prevent or at least reduce impurities from entering the array on the substrate 100 from the substrate 100 and to additionally protect the array on the upper side of the substrate 100.

The first source-drain electrode 132 may be connected to the light-shielding pattern 115 in addition to being connected to the active layer 125 to stabilize the potential of the light-shielding pattern 115.

The second insulating layer 122 between the active layer 125 and the gate electrode 131 may serve as a gate insulating layer.

Third and fourth insulating layers 123 and 124 may be provided between the gate electrode 131 and the first and second source-drain electrodes 132 and 133 for interlayer insulation. In the illustrated example, two insulating layers are provided, but the present disclosure is not limited thereto. For example, a single insulating layer may be provided between the gate electrode 131 and the first and second source-drain electrodes 132 and 133. Alternatively, three or more insulating layers may be provided between the gate electrode 131 and the first and second source-drain electrodes 132 and 133.

At least one electrode of the transistor TFT and at least one electrode of the storage capacitor CS may be disposed on the same layer.

For example, when multiple inorganic layers are provided between the gate electrode 131 and the first and second source-drain electrodes 132 and 133, a first storage electrode 127 may be disposed on the same layer as the gate electrode 131, and a second storage electrode 128 may be disposed on the third insulating layer 123 covering the first storage electrode 127 and overlapping the first storage electrode 127. The illustrated example is an example, and the first and second storage electrodes 127 and 128 of the storage capacitor may be disposed on different layers. In some cases, the storage capacitor may be disposed under the transistor TFT.

The light-shielding pattern 115, the gate electrode 131, the first and second source-drain electrodes 132 and 133, and the first and second storage electrodes 127 and 128 may each include one of aluminum (Al), titanium (Ti), copper (Cu), chromium (Cr), molybdenum (Mo), and tungsten (W).

A plurality of transistors TFTs is provided in each subpixel, and some of the plurality of transistors may serve as switching transistors and others may serve as driving transistors. For different functions, a switching transistor and a driving transistor may have different lamination structures or may have different widths and/or lengths of active layer channels.

For example, when the transistor TFT illustrated in FIG. 3 is an oxide transistor including an oxide semiconductor in the active layer 125, a crystalline transistor including crystalline silicon as an active layer may be additionally provided between the substrate 100 and the first insulating layer 121. The crystalline transistor may be included in the subpixel, and in some cases, may be included as a part of the gate driver 205 in the non-active area NA.

The second storage electrode 128 may have the same layer as one electrode of the transistor illustrated in FIG. 4 and FIG. 5 and other transistors.

The first to fourth insulating layers 121, 122, 123, and 124 may each include an inorganic insulating layer, for example, a silicon oxide (SiOx) layer, a silicon nitride (SiNx) layer, a silicon oxynitride (SiOxNy) layer, or a multilayer layer in which some thereof are laminated.

A first organic layer 141 and a second organic layer 142 that protect the transistor TFT and the storage capacitor CS may be provided on the fourth insulating layer 124. In some cases, the second organic layer 142 may be omitted.

The first organic layer 141 may be disposed on the transistor TFT or on the fourth insulating layer 124 to protect the transistor TFT and alleviate a step caused by the transistor TFT.

A connection electrode 135 or a shielding pattern may be further provided on the first 141, organic layer corresponding to the circuit components of subpixels, such as the transistor TFT and the storage capacitor Cs. The connection electrode 135 may serve to electrically connect the transistor TFT and the first electrode 151 of the light-emitting element 150. The connection electrode 135 of the shielding pattern may serve to prevent the operation of the circuit components disposed thereunder from causing electrical interference with the operation of the light-emitting element 150 disposed thereabove.

The first and second organic layers 141 and 142 cover the transistor TFT and are disposed on the fourth insulating layer 124 to provide a flat surface.

The first organic layer 141 and the second organic layer 142 may each include an organic material. The organic material may include one or more of acrylic resin, phenolic resin, polyimide resin, unsaturated polyester resin, polyamide resin, benzocyclobutene, polyphenylene resin, and polyphenylene sulfide resin.

In addition to the first to fourth insulating layers 121, 122, 123, and 124 described above, various functional organic layers or inorganic layers may be additionally provided between the substrate 100 and the first organic layer 141.

The light-emitting element 150 is disposed on the second organic layer 142. The light-emitting element 150 may be electrically connected to the transistor TFT through an organic layer 140. The light-emitting element 150 includes a first electrode 151, an intermediate layer 152, and a second electrode 153.

The first electrode 151 may serve as an anode. The first electrode 151 may be connected to the transistor TFT by passing through the second organic layer 142 and the first organic layer 141. In the illustrated example, the connection electrode 135 is further provided between the first electrode 151 and the transistor TFT is shown, the transistor TFT and the connection electrode 135 are connected, and the connection electrode 135 and the first electrode 151 are connected, but the second source/drain electrode 133 of the transistor TFT and the first electrode 151 of the light-emitting element 150 may be directly connected without the connection electrode 135.

The first electrode 151 may include a metal material having high reflectivity. For example, the first electrode 151 may be formed in a multilayer structure such as a laminated structure of aluminum (Al) and titanium (Ti) (Ti/Al/Ti), a laminated structure of aluminum (Al) and ITO (ITO/Al/ITO), an APC (Ag/Pd/Cu) alloy, a laminated structure of an APC alloy and ITO (ITO/APC/ITO), or a laminated structure of silver (Ag) and molybdenum/titanium alloy (Ag/MoTi), or may include a single-layer structure made of one material selected from silver (Ag), aluminum (Al), molybdenum (Mo), gold (Au), magnesium (Mg), calcium (Ca), or barium (Ba), or two or more alloy materials. The first electrode 151 may be referred to as a reflective electrode.

The intermediate layer 152 is provided on the first electrode 151. The intermediate layer 152 may include a hole injection layer, a hole transport layer, an organic emission layer, an electron transport layer, and an electron injection layer.

The edge of the first electrode 151 may overlap with a bank 155. An area of the first electrode 151 exposed from the bank 155 may be an emission area EA1, EA2, and EA3. The bank 155 may include a light-blocking organic material, such as a transparent resin or a black pigment.

When a voltage is applied to the first electrode 151 and the second electrode 153, holes and electrons move to the organic emission layer through the hole injection layer and the hole transport layer, and the electron injection layer and the electron transport layer, holes and electrons combine with each other to form excitons in the organic emission layer, and the excitons drop from an excited state to a ground state, causing light emission.

When the intermediate layer 152 includes multiple layers, each or some of the multiple layers of the intermediate layer 152 may be provided in common throughout the entire active area AA. In some cases, one or some of the multiple layers of the intermediate layer 152 may be selectively provided in the emission areas EA1, EA2, and EA3. The light-emitting element 150 may have a tandem configuration in which a stack including an emission layer, a hole-transport common layer related to hole transport disposed under the emission layer, and an electron-transport common layer related to electron transport disposed under the emission layer is provided as a unit stack, a plurality of stacks is provided between the first and second electrodes 151 and 153, and a charge generation layer is provided between the plurality of stacks. In the tandem configuration, each layer including the charge generation layer of the intermediate layer 152 may be a common layer disposed on the overall surface of the active area AA.

The intermediate layer 152 may include at least one of a red emission layer emitting red light, a green emission layer emitting green light, or a blue emission layer emitting blue light. The red emission layer, the green emission layer, and the blue emission layer may be provided on the first electrode 151 for respective subpixels SP. The red emission layer may be disposed in a red subpixel, the green emission layer may be disposed in a green subpixel, and the blue emission layer may be disposed in a blue subpixel, but the present disclosure is not necessarily limited thereto and at least two organic emission layers among the red emission layer, the green emission layer, and the blue emission layer may be laminated and disposed in one subpixel SP.

The intermediate layer 152 may be a white emission layer emitting white light. In this case, the white emission layer may be configured as a common layer in which a plurality of unit stacks is laminated and integrally disposed in a plurality of subpixels.

The second electrode 153 may be a common layer that is commonly disposed in the subpixels SP and supplied with the same voltage. To this end, the second electrode 153 may be disposed to extend from the active area AA to a part of the non-active area NA.

The second electrode 153 may be a transmissive or reflective-transmissive electrode. The second electrode 153 may include a transparent conductive material such as indium tin oxide (ITO) or indium zinc oxide (IZO) that can transmit light, or a semi-transmissive conductive material such as magnesium (Mg), silver (Ag), or an alloy of magnesium (Mg) and silver (Ag). When the second electrode 153 includes a semi-transmissive conductive material, the light emission efficiency can be increased by the microcavity effect. When the second electrode 152 includes a semi-transmissive conductive material, the second electrode 153 may be thin sufficiently to transmit light. For example, the thickness of the second electrode 153 may be 200 Å or less.

The first electrode 151 may prevent or at least reduce light generated in the intermediate layer 152 from being transmitted to a light-shielding component below the first electrode 151 by including a reflective electrode. The light generated in the intermediate layer 152 resonates between the second electrode 153 and the first electrode 151, and can finally be emitted upward through the second electrode 153. Since the first electrode 151 includes a reflective component, even if the first electrode 151 overlaps with wiring lines and the transistor TFT, light emitted from the light-emitting element 150 is visible in the emission areas EA1, EA2, and EA3 without being affected by the arrangement of the wiring lines and the transistor TFT.

The intermediate layer 152 and the second electrode 153 among the components of the light-emitting element 150 may be independently disposed in the transparent area TA. Alternatively, at least a portion of the intermediate layer 152 and the second electrode 153 may be omitted to ensure transparency of the transparent area TA.

The transparent area TA does not have the first electrode 151 compared to the light-emitting element 150 in the emission areas EA1, EA2, and EA3. The intermediate layer 152 and the second electrode 153 may be provided or omitted independently in the transparent area TA. At least one of the hole injection layer, the hole transport layer, the electron transport layer, and the electron injection layer of the intermediate layers 152 may extend laterally from the emission areas EA1, EA2, and EA3 and may be provided in the transparent area TA. As shown in FIG. 4 and FIG. 5, the second electrode 153 may be provided in the transparent area TA. In some cases, the second electrode 153 may be omitted from the transparent area TA to increase the transmittance of the transparent area TA.

When the intermediate layer 152 and the second electrode 153 are provided in the transparent area TA, the use of a fine metal mask (FMM) requiring a fine opening at the time of forming each layer can be omitted, and yield improvement and process simplification are expected.

The encapsulation layer 160 is provided on the light-emitting element 150 to protect and seal the light-emitting element.

The encapsulation layer 160 may be provided as a single layer or as a multilayer layer. When the encapsulation layer 160 is a multilayer layer, for example, an inorganic encapsulation layer and an organic encapsulation layer may be disposed in an alternating form. The uppermost layer and the lowermost layer of the encapsulation layer 160 may be inorganic encapsulation layers, which is advantageous in preventing or at least reducing external air such as moisture from penetrating.

The encapsulation layer 160 planarizes the surface unevenness of the light-emitting element 150. Accordingly, the touch sensor 170 provided on the encapsulation layer 160 and detecting an external touch is disposed on the flat encapsulation layer 160.

The touch sensor 170 may include a touch buffer layer 171 disposed on the encapsulation layer 160, a first wiring layer 172 disposed on the touch buffer layer 171, a touch insulating layer 173 covering the first wiring layer 172 and planarizing the surface, a second wiring layer 174 disposed on the touch insulating layer 173 and connected to a part of the first wiring layer 172, and a first protective layer 175 disposed on the second wiring layer 174 and providing a flat surface of the external light reflection prevention layer 180.

The first protective layer 175 is provided to improve metal protection and adhesion of the first and second wiring layers 172 and 174.

The touch buffer layer 171, the touch insulating layer 173, and the first protective layer 175 may be inorganic layers made of silicon oxide (SiOx), silicon nitride (SiNx), or silicon oxynitride (SiOxNy).

The external light reflection prevention layer 180 including a light-shielding layer 181 disposed in an area other than the emission areas EA1, EA2, and EA3 and the transparent area TA, and color filters 182 (182a, 182b, and 182c) disposed to correspond to the emission areas EA1, EA2, and EA3 may be provided on the touch sensor 170. The light-shielding layer 181 and the color filters 182 (182a, 182b, and 182c) included in the external light reflection prevention layer 180 may serve to absorb external light coming from above toward the display device 1000, thereby preventing or at least reducing reflection of the external light by the metals of the touch sensor 170 and the light-emitting element 150. In this case, the external light reflection prevention layer 180 disposed on the touch sensor 170 can serve as a color filter array expressing colors and replace a polarizing plate, and thus the polarizing plate positioned above the light-emitting element in the display device 1000 can be omitted, thereby achieving a slim and simplified structure of the display device.

The light-shielding layer 181 may be disposed to cover at least the area occupied by the first wiring layer 172 and the second wiring layer 174 of the touch sensor 170, thereby preventing or at least reducing external light from being transmitted to the first wiring layer 172 and the second wiring layer 174 and preventing or at least reducing glinting due to the wiring layers of the touch sensor 170. The first wiring layer 172 and the second wiring layer 174 are disposed in the area between emission areas, between transparent areas, and between the emission area and a transparent area, and are covered by the light-shielding layer 181.

The emission area EA may include, for example, the first to third emission areas EA1, EA2, and EA3. The color filter 182 may include the first color filter 182a disposed in the first emission area EA1, the second color filter 182b disposed in the second emission area E2, and the third color filter 182c disposed in the third emission area EA3. For example, the first color filter 182a, the second color filter 182b, and the third color filter 182c may be a red color filter, a green color filter, and a blue color filter, respectively. The red color filter selectively transmits red light and absorbs light of the remaining wavelengths. The green color filter selectively transmits green light and absorbs light of the remaining wavelengths. The blue color filter selectively transmits blue light and absorbs light of the remaining wavelengths.

The first to third emission areas EA1, EA2, and EA3 may include emission layers emitting different colors in the intermediate layer 152 and thus emit different colors. In this case, the color filter 182 may transmit the color emitted from the corresponding emission area more clearly. Alternatively, the light-emitting element 150 included in each of the first to third emission areas EA1, EA2, and EA3 may emit white light, and transmit light of a color corresponding to each emission area through the color filter 182 in the external light reflection prevention layer 180 above the touch sensor 170. When the light-emitting element emits white light, the intermediate layer 152 may be formed in a form in which a plurality of stacks including emission layers emitting a plurality of different colors is laminated.

The color filters 182a, 182b, and 182c provided corresponding to the emission areas EA1, EA2, and EA3 overlaps the entire emission areas EA1, EA2, and EA3 and have edges outward than the edges of the emission areas EA1, EA2, and EA3 to overlap a part of the light-shielding layer 181 located outside the emission areas EA1, EA2, and EA3. The color filters 182a, 182b, and 182c may partially overlap the bank 155 between the emission areas EA1, EA2, and EA3. Therefore, the color filters 182a, 182b, and 182c) between the emission areas EA1, EA2, and EA3 overlap with the light-shielding layer 181, thereby preventing or at least reducing light leakage and blocking light coming from the upper side to the side and light emitted from each of the emission areas EA1, EA2, and EA3 and traveling in the oblique direction to adjacent subpixels, thereby enabling viewing angle light shielding.

The external light reflection prevention layer 180 may further include a second protective layer 183 that compensates for the surface step between the light-shielding layer 181 and the color filters 182a, 182b, and 182c and planarizes the upper surface. The second protective layer 183 is a transparent insulating layer and may be an organic layer such as an acrylic resin, an epoxy resin, an ester resin, a polyimide resin, or a polyamide resin.

The second protective layer 183 serves as a cover layer that protects the lower components at the outermost side of the display device 1000 and may planarize the surface of the inner components.

Meanwhile, in the transparent display device 1000 according to an embodiment of the present disclosure, at least the touch buffer layer 171, the touch intermediate insulating layer 173, and the first protective layer 175 that are inorganic insulating layers among the components disposed the encapsulation layer 160 may be removed from the transparent area TA. This is for the purpose of preventing or at least reducing interfacial reflection occurring at the interface between the inorganic insulating layers of the touch sensor 170 which have relatively high refractive indices to improve the purity and the transmittance of the transparent area TA.

The touch buffer layer 171, the touch intermediate insulating layer 173, and the first protective layer 175 may be patterned at the boundary between the transparent area TA and the surrounding area and may have a side surface at the surrounding area of the transparent area TA.

The transparent area TA does not overlap with the first and second wiring layers 172 and 174, the light-shielding layer 181, and the color filter 182, and the second protective layer 183 positioned at the uppermost side on the substrate 100 may be disposed in contact with the upper surface of the encapsulation layer 160 in the plurality of transparent areas TA. The second protective layer 183 may be disposed relatively deeper in the transparent area TA than in the emission areas EA (EA1, EA2, and EA3), and thus the thickness of the second protective layer 183 in the transparent area TA may be greater than the thickness in the emission areas EA (EA1, EA2, and EA3).

Since the encapsulation layer 160 and the second protective layer 183 have similar refractive indices, interfacial reflection at the interface where the encapsulation layer 160 and the second protective layer 183 meet hardly occurs, and thus purity can be secured along with transmittance in the transparent area TA.

In addition, the second protective layer 183 is an organic insulating layer that is advantageous for planarization compared to the inorganic insulating layers 171, 173, and 175 on the encapsulation layer 160, and can improve transmittance by reducing refraction or reflection occurring in the transparent area TA according to planarization.

“Purity” described in the present disclosure is defined as “the ratio of brightness changed due to influence of diffraction and scattering to highest brightness considering black brightness of background passing through transparent display device”, and can be defined by the following expression 1. The purity is also referred to as “clearance”.

$$Purity ( \% ) = L ( Brightness ) pattern - passing / \\ L ( Brightness ) total - passing * 100 \qquad [ Expression 1 ]$$

Here, L (Brightness) total-passing is the highest brightness value considering the black brightness of the background passing through the transparent display device, and means “reference luminance”. In addition, L (Brightness) pattern-passing is a value changed due to the influence of diffraction and scattering, and means a “changed luminance” value due to diffraction and scattering when the minimum pattern passes through the transparent display device.

Purity can be evaluated by the following expressions.

$${P}_{sample} = \frac{{L}_{CW , sample} - {L}_{FK , sample}}{{L}_{FW , sample} - {L}_{FK , sample}} \qquad [ Expression 2 ]$$

Here, L_{CW,sample} represents the luminance when a full white test pattern is observed through a first opening of a transparent display device by a light meter. L_{FK,sample} represents the luminance when a full black test pattern is observed through the first opening of the transparent display device by the light meter. L_{CW,sample} represents the luminance when a circular white test pattern is observed through the first opening of the transparent display device by the light meter. The purity is obtained by measuring the ratio of the amount of light within a small viewing angle of a circular white pattern to the total amount of light transmitted through the transparent display device.

Here, L_{FW,sample}, L_{FK,sample}, and L_{CW,sample} are evaluated by placing the light meter LMD on one side and a reference display on the other side with the transparent display device positioned therebetween, displaying a first opening pattern with a viewing angle of 1° on the transparent display device, and measuring luminance values obtained from test patterns (full white pattern, full black pattern, and circular white pattern) of the reference display through the first opening pattern of the transparent display device through the light meter.

$${P}_{ur} = \frac{{P}_{sample}}{{P}_{ref}} \times 100 \qquad [ Expression 3 ]$$

In Expression 3, the reference purity P_{ref} is evaluated by directly observing the test patterns through the light meter LMD, as represented by Expression 4, and is a measurement of luminance value change without passing through the transparent display device.

$${P}_{ref} = \frac{{L}_{CW , w / o} - {L}_{FK , w / o}}{{L}_{FW , w / o} - {L}_{FK , w / o}} \qquad [ Expression 4 ]$$

That is, the reference purity P_{ref} of Expression 4 represents the ratio of the difference L_{CW,w/o}-L_{FK,w/o} between the luminance L_{CW,w/o} of the circular white pattern and the luminance L_{FK,w/o} of the full black pattern to the difference L_{FW,w/o}-L_{FK,w/o} between the luminance L_{FW,w/o} of the full white pattern and the luminance L_{FK,w/o} of the full black pattern.

As in Expression 3, the purity of the transparent display device can be evaluated through the measured purity Pₛₐₘₚₗₑ compared to the reference purity P_{ref}. The higher the purity value, the less refraction/diffraction occurs and the clearer the see-through image.

The transparent display device not only simply performs a transmission function but also performs image display, and for image display, a plurality of metal lines is disposed in a grid shape and the bank 155 is disposed to overlap with the metal lines.

Therefore, a diffraction image is generated due to overlapping of patterns such as the metal lines and the bank in a grid shape, and this diffraction may cause reduction in the purity when viewing an image on the back side of the substrate. The transparent display device of the embodiments of the present disclosure removes interfacial refraction and reflection components of the transparent area by removing the cause of reduced purity, thereby improving purity along with transmittance.

The transparent display device 1000 of an embodiment of the present disclosure improves both transmittance and purity in the transparent area TA by disposing a plurality of metal lines and the bank such that they do not overlap with the transparent area TA and removing a plurality of inorganic insulating layers that cause interfacial reflection from at least the transparent area TA on the encapsulation layer 160.

The higher the purity value, the less the influence of refraction/diffraction and the clearer the view. In the transparent display device, a back image means a see-through image, and unlike characteristics such as high contrast and brightness for evaluating display, it is evaluated by different scales from the display characteristics of a general display device as described above, and purity is used as one of the different scales.

Meanwhile, in the transparent display device of the embodiments of the present disclosure, improvement of purity means that an image behind the substrate 100 of the transparent display device 1000 is visible on the second protective layer 183 on the opposite side, and an image on the second protective layer 183 is visible on the lower side of the substrate 100, and means that a background image is less affected by diffraction/refraction on the opposite side, and thus the boundary part of the background image is clearly visible.

In the transparent display device 1000 of the present disclosure, at least the insulating layer configuration on the encapsulation layer 160 among the components of the transparent area TA is changed. The transmittance is improved by simply omitting a light-blocking component in the transparent area TA, and the patterned insulating layers 171, 173, and 175 on the encapsulation layer 160 are applied such that the background image behind the substrate 100 is clearly visible in the transparent display device.

As shown in FIG. 5, the touch buffer layer 171, the touch intermediate insulating layer 173, and the first protective layer 175 may have side surfaces around each transparent area TA. In addition, the touch buffer layer 171, the touch intermediate insulating layer 173, and the first protective layer 175 may be patterned through the same process and thus can have the same side surface.

The touch buffer layer 171, the touch intermediate insulating layer 173, and the first protective layer 175 are disposed such that they do not overlap each of the plurality of transparent areas TA illustrated in FIG. 3, and interfacial reflection occurring at the interface of inorganic insulating layers in the transparent areas TA can be effectively prevented or at least reduced.

The touch buffer layer 171, the touch intermediate insulating layer 173, and the first protective layer 175 may include, for example, a silicon nitride layer, a silicon oxide layer, or a silicon oxynitride layer.

The refractive index of each of the touch buffer layer 171, the touch intermediate insulating layer 173, and the first protective layer 175 may be greater than the refractive index of the second protective layer 183.

The second protective layer 183 located on the uppermost surface of the transparent display device 1000 planarizes the surface and protects components thereunder from external impact and the like. The second protective layer may be an organic insulating layer. The second protective layer 183 has a lower refractive index than the touch buffer layer, the touch intermediate insulating layer 173, and the first protective layer 175, and may include a material having a refractive index similar to that of the encapsulation layer 160.

The encapsulation layer 160 is formed by alternately laminating an organic encapsulation layer and an inorganic encapsulation layer such that the uppermost component becomes an inorganic encapsulation layer. Accordingly, even if the second protective layer 183 and the inorganic encapsulation layer of the encapsulation layer 160 are in direct contact with each other in the transparent area TA, the inorganic encapsulation layer is relatively thicker than the inorganic insulating layers 171, 173, and 175 included in the touch sensor, and thus hardly causes optical interfacial reflection compared to the inorganic insulating layers 171, 173, and 175 included in the touch sensor.

At least one of the first wiring layer 172 and the second wiring layer 174 may be a sensor electrode or a touch electrode. In some cases, the second wiring layer 174 may include sensor electrodes spaced apart from each other and a touch electrode, the first wiring layer 172 may be used as a bridge electrode, and the touch electrode may have a connection pattern 174e connected to the bridge electrode of the first wiring layer 172 at a portion where adjacent sensor electrodes of the second wiring layer 174 are spaced apart from each other. Here, a touch contact hole CT between the first wiring layer 172 and the connection pattern 174e may be disposed, for example, in the touch intermediate insulating layer 173, and the area where the touch contact hole CT is located may overlap with the bank 155.

The touch contact hole CT is located such that it does not overlap with the plurality of emission areas EA (EA1, EA2, and EA3 and the plurality of transparent areas TA, and thus does not affect light-emitting display and transparent display.

The first wiring layer 172 and the second wiring layer 174 of the touch sensor 170 may be disposed to overlap with the light-shielding layer 181. That is, the first wiring layer 172 and the second wiring layer 174 forming the touch sensor 170 are covered by the light-shielding layer 181, thereby preventing or at least reducing glinting due to the metal of the first and second wiring layers 172 and 174 from being visible.

The bank 155 is disposed at the edge of each of the plurality of first electrodes 151 and in the spaced area between the plurality of first electrodes 151.

As shown in FIG. 5, an edge BME2 of the light-shielding layer 181 of the external light reflection prevention layer 180 may be closer to the plurality of transparent areas TA than an edge BKOE of the bank 155. In addition, an edge BME1 of the light-shielding layer 181 of the external light reflection prevention layer 180 may be closer to the plurality of transparent areas TA than the edge BKOE of the bank.

In addition, as shown in FIG. 4, the edge BME1 of the light-shielding layer 181 may be closer to the plurality of emission areas EA (EA1, EA2, and EA3) than an edge BKIE of the bank 155.

Here, BME1 means a light-shielding layer end line adjacent to an emission area, and BME2 means a light-shielding end line adjacent to a transparent area. BKIE means a bank end line adjacent to an emission area, and BKOE means a bank end line adjacent to a transparent area.

In the transparent display device according to an embodiment of the present disclosure, the light-shielding layer 181 of the external light reflection prevention layer 180 completely overlaps the bank 155 and is arranged in an area larger than the bank 155, and thus the light-shielding layer 181 can completely cover the bank 155. Therefore, the phenomenon in which light passes through the edge or end of the bank 155 between the bank 155 and the light-shielding layer 181 and is refracted to pass through the transparent area TA can be prevented, thereby reducing or preventing transmission of light refracted and diffracted in the transparent area TA, which is more effective in improving the purity of the transparent area TA.

Meanwhile, the bank 155 includes a light-shielding material or a light-absorbing material. When the bank 155 includes a light-blocking material or a light-absorbing material, the external light reflection visibility of the external light reflection prevention layer 180 can be improved more effectively.

In the display device according to an embodiment of the present disclosure, the emission areas EA1, EA2, and EA3 and the transparent areas TA are spaced apart from each other on a plane, as shown in FIG. 3.

In the display device according to an embodiment of the present disclosure, the emission areas EA1, EA2, and EA3 emitting different lights may be spaced apart from each other, and the transparent areas TA may be spaced apart from each other. In addition, each of the emission areas EA1, EA2, and EA3 may be disposed between the transparent areas TA and spaced apart from the transparent areas TA.

Referring to FIG. 3, in the display device according to an embodiment of the present disclosure, the transparent areas TA may be disposed in one row with the data line DL interposed therebetween, and the emission areas EA1, EA2, and EA3 are disposed in the next row. That is, the rows of the transparent areas TA and the rows of the emission areas EA1, EA2, and EA3 are arranged alternately. This is an example, and in some cases, the emission areas may be disposed in a row where the transparent areas are disposed, overlapping the area where wiring lines between the transparent areas are located in other embodiments of the present disclosure.

The transparent areas TA are areas that do not overlap wiring lines such as the gate line GL and the data line DL, and differs from the emission areas EA1, EA2, and EA3 that overlap at least one wiring line. In addition to the gate line GL and the data line DL illustrated in FIG. 3, wiring lines may include the first power voltage line VSSL for supplying the low-level voltage EVSS or a common voltage included in the subpixel of FIG. 2, and the second power voltage line VDDL for supplying the high-level voltage EVDD. At least some of the emission areas EA1, EA2, and EA3 may overlap with these first and second power voltage lines VSSL and VDDL.

The area excluding the transparent areas TA may be a non-transparent area NTA, and the non-transparent area NTA may include an area overlapping with the emission areas EA1, EA2, and EA3 and an area that does not overlap with the emission areas EA1, EA2, and EA3. The bank 155 may be disposed in the area of the non-transparent area NTA that does not overlap with the emission areas EA1, EA2, and EA3.

The bank 155 may have openings corresponding to the transparent areas TA and the emission areas EA1, EA2, and EA3. The edge of the first electrode 151 of the light-emitting element 150 may overlap with the bank 155, and areas of the first electrode 151 exposed from the bank 155 may become the emission areas EA1, EA2, and EA3.

In FIG. 3, the first and third emission areas EA1 and EA3 are illustrated as octagons, and the second emission area EA2 is illustrated as a square, but the embodiment of the present disclosure is not limited thereto. In addition to an octagon or a square, the emission areas EA1, EA2, and EA3 may be a polygon including a hexagon, a decagon, a dodecagon, etc., or may be an area having a round portion. Each of the emission areas EA1, EA2, and EA3 may have a side parallel to a side of another adjacent emission area and a side of the transparent area TA.

The display device 1000 of the embodiments of the present disclosure includes the touch sensor 170 and the external light reflection prevention layer 180 provided on the encapsulation layer 160 that protects the light-emitting element 150. Since the transparent area TA is provided under the touch sensor 170, the first and second wiring layers 172 and 174 of the touch sensor 170 and the external light reflection prevention layer 180 are disposed to maximize the transmittance of the transparent area TA.

The first and second wiring layers 172 and 174 of the touch sensor 170 include a metal component, have little resistance in transmitting a touch detection signal and a touch sensing signal, and may have a narrow line width. In the display device 1000 of the embodiments of the present disclosure, the first and second wiring layers 172 and 174 of the touch sensor 170 include a metal component, and thus the first and second wiring layers 172 and 174 are disposed such that they do not overlap with the emission areas EA1, EA2, and EA3 and the transparent area TA.

The second wiring layer 174 may be a plurality of spaced sensor layer electrodes that detect electrostatic capacitance that changes according to touch, and the first wiring layer 172 may serve to electrically connect the spaced sensor layer electrodes of the second wiring layer 174 in a different layer from the second wiring layer 174.

In the embodiments which will be described below, the first wiring layer 172 adjacent to the encapsulation layer 150 will be described as a bridge electrode layer, and the second wiring layer 174 located far from the encapsulation layer 150 will be described as a sensor electrode layer electrode, but the embodiments of the present disclosure are not limited thereto. In another embodiment of the present disclosure, the bridge electrode layer may be located on the upper side and the sensor electrode layer may be located on the lower side.

Referring to FIG. 3, the first wiring layer 172 may extend along the upper and lower edges of the plurality of emission areas EA1, EA2, and EA3 arranged in the same row. The first wiring layer 172 may have a line shape that extends in the horizontal direction in which the emission areas EA1, EA2, and EA3 are arranged outside of the emission areas EA1, EA2, and EA3 of FIG. 3.

Referring to FIG. 3, The second wiring layer 174 may be disposed in the column direction and may extend in the vertical direction intersecting the first direction with respect to the first and third emission areas EA1 and EA3. The area where the first and second wiring layers 172 and 174 are disposed overlaps with the bank 155.

The light-shielding layer 181 and the bank 155 can effectively prevent or at least reduce light from traveling in the oblique direction from the emission areas EA1, EA2, and EA3 and light from traveling in the oblique direction from above by shielding them together, thereby achieving viewing angle light shielding.

Meanwhile, in the transparent display device 1000 according to an embodiment of the present disclosure, the transparent area TA does not have a light-blocking metal component, and has a portion in which inorganic insulating layers are patterned and removed in the components above the encapsulation layer 160.

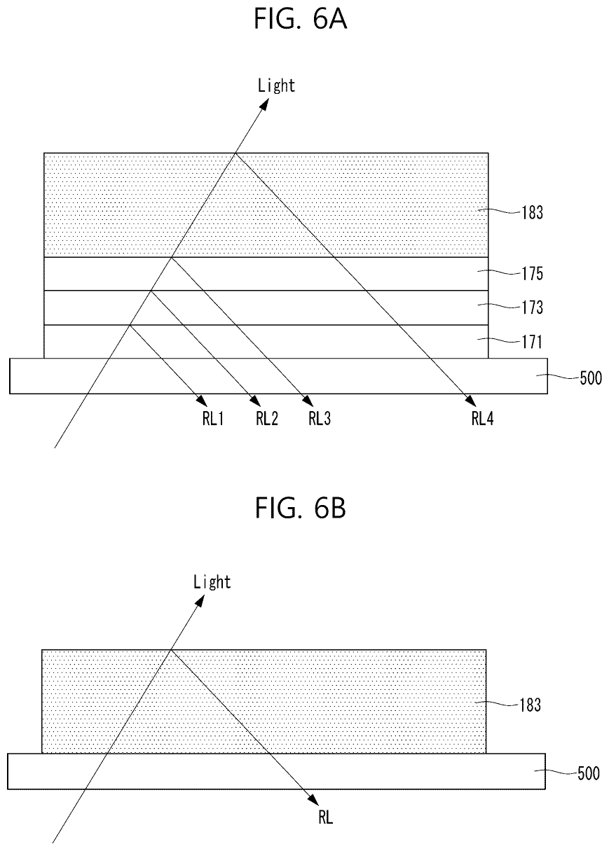

FIG. 6A and FIG. 6B show interfacial reflection in first and second experimental examples.

As shown in FIG. 6A, the first experimental example EX1 shows a structure in which the touch buffer layer 171, the touch intermediate insulating layer 173, the first protective layer 175, and the second protective layer 183 are sequentially formed on a substrate 500. In the first experimental example EX1, when light passes through the substrate 500 from the lower side of the substrate 500, first interface reflected light RL1 between the touch buffer layer 171 and the touch intermediate insulating layer 173, second interface reflected light RL2 between the touch intermediate insulating layer 173 and the first protective layer 175, third interface reflected light RL3 between the first protective layer 175 and the second protective layer 183, and fourth interface reflected light RL4 between the surface of the second protective layer 183 and the outside air are generated.

On the other hand, as in the transparent area TA of the transparent display device according to an embodiment of the present disclosure, in the second experimental example EX2 shown in FIG. 6B, the second protective layer 183 is disposed on the substrate 500, and thus there is no component that causes interfacial reflection within the second protective layer 183. Accordingly, the second experimental example EX2 is almost free from the influence of interfacial reflection compared to the first experimental example EX1, and light passing through the lower side of the substrate 500 passes through the second protective layer 183 on the substrate 500 and thus only a small amount of reflected light RL is generated on the surface of the second protective layer 183 and can be transmitted as clear light with high transmittance and without the influence of refraction and reflection.

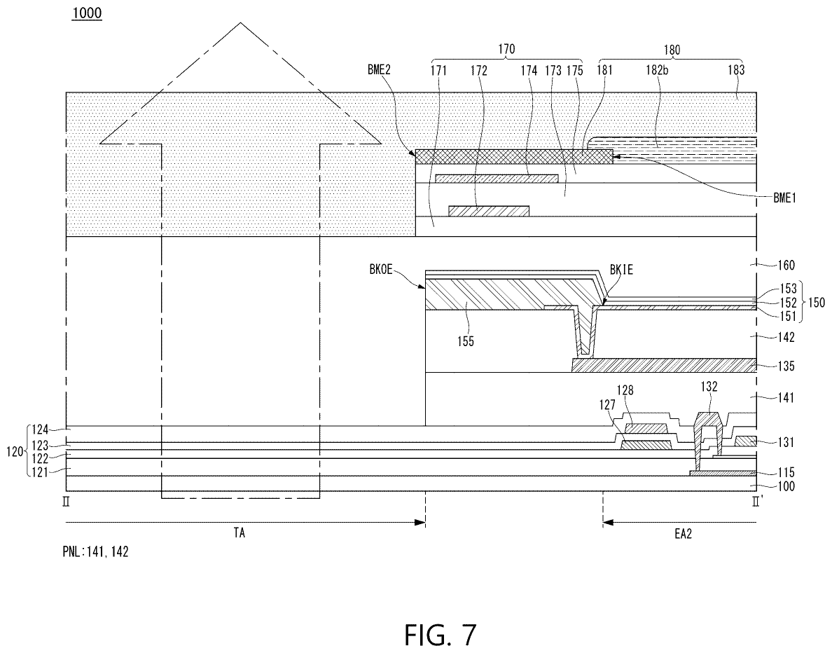

FIG. 7 to FIG. 9 are cross-sectional views along lines II-II′ of FIG. 3 according to other embodiments.

As shown in FIG. 7, a transparent display device according to another embodiment of the present disclosure has a configuration in which the first and second organic layers 141 and 142 below the encapsulation layer 160 have been further removed from the transparent area TA compared to the configuration of FIG. 5. In this case, the space of the first and second organic layers 141 and 142 may be filled with the encapsulation layer 160. The first and second organic layers 141 and 142 may be removed from the transparent area TA by being patterned in the process of forming a contact hole CTA connecting the first electrode 151 and the connection electrode 135, for example.

When the first and second organic layers 141 and 142 are omitted from the transparent area TA, the transmittance is improved compared to the structure of FIG. 5 described above, and the purity can also be improved to an equivalent level or higher.

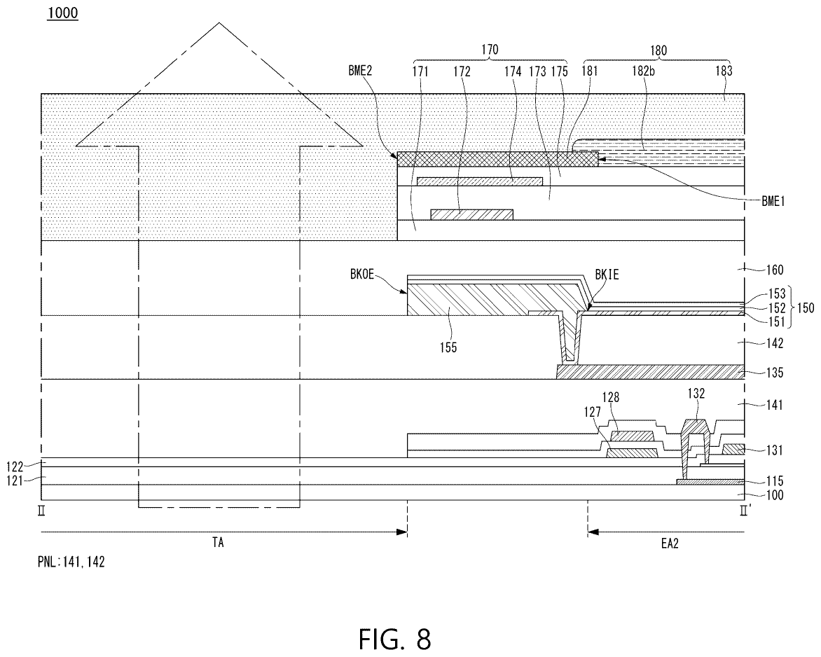

As shown in FIG. 8, a transparent display device according to another embodiment of the present disclosure has a configuration in which the third insulating layer 123 and the fourth insulating layer 124 have been removed from the transparent area TA compared to the configuration of FIG. 5. Here, the third and fourth insulating layers 123 and 124 serve as interlayer insulating layers of a transistor TFT and are a type of inorganic insulating layer. Since they have higher refractive indices than the first and second organic layers 141 and 142 (insulating layers), they can further reduce interfacial reflection in the transparent area TA compared to the structure of the first and second organic layers 141 and 142 of FIG. 7 described above, and thus the purity can be improved more effectively.

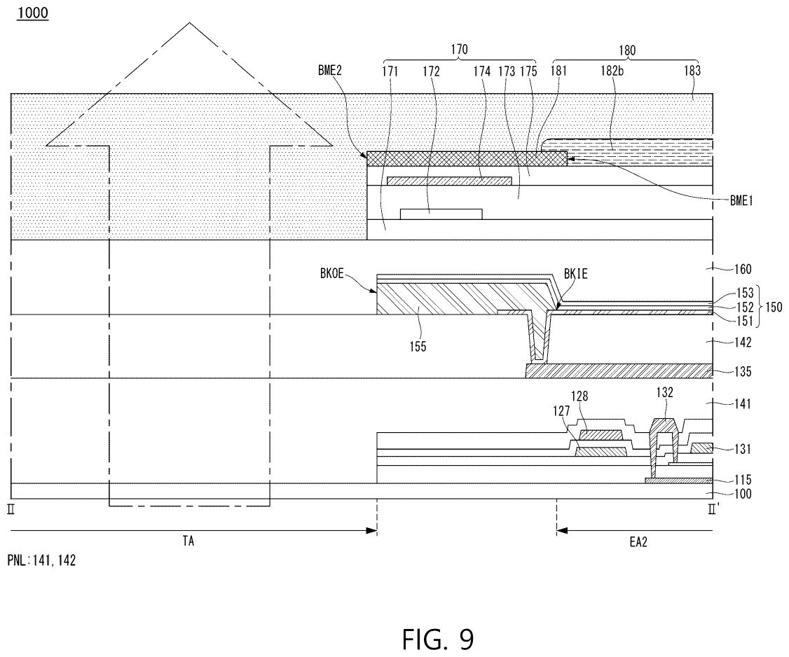

As shown in FIG. 9, a transparent display device according to another embodiment of the present disclosure has a configuration in which the first to fourth insulating layers 121, 122, 123, and 124 have been removed from the transparent area TA compared to the configuration of FIG. 5. Here, the third and fourth insulating layers 123 and 124 serve as interlayer insulating layers of a transistor TFT, the first insulating layer 121 is a buffer layer, and the second insulating layer 122 is a gate insulating layer, which are inorganic insulating layers. Since the first to fourth insulating layers 121, 122, 123, and 124 have higher refractive indices than the first and second organic layers 141 and 142 (insulating layers), they can further reduce interfacial reflection in the transparent area TA compared to the structure of the first and second organic layers 141 and 142 of FIG. 7 described above, and thus the purity can be improved more effectively.

In addition to the examples illustrated in FIG. 5 and FIG. 7 to FIG. 9, at least one of the first to fourth insulating layers 121, 122, 123, and 124 and the first and second organic layers 141 and 142 in the transparent area TA may be removed to reduce the path of the area in which light propagates in the transparent area TA, thereby increasing the purity of light. By combining the examples of FIG. 7 and FIG. 8 or FIG. 9, the first and second organic layers 141 and 142 may be omitted in the transparent area TA, and at least one of the first to fourth insulating layers 121, 122, 123, and 124 may be removed.

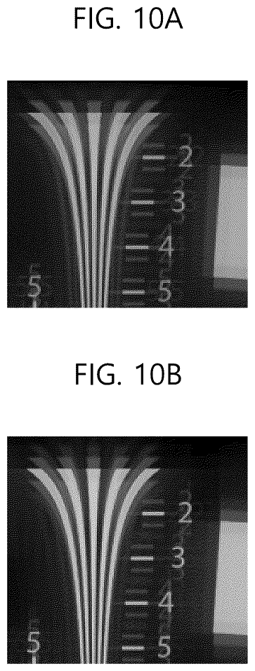

FIG. 10A and FIG. 10B are photographs showing images before and after removal of an inorganic insulating layer in the transparent area.

Compared to the see-through image before the removal of the inorganic insulating layer in the transparent area of FIG. 10A, the see-through image after the removal of the inorganic insulating layer in the transparent area of FIG. 10B shows improvements in both purity and transmittance.

Table 1 below shows the relationship between transmittance and purity according to the degree of pattern removal.

TABLE 1

| | EX3 | EX4 | EX5 | EX6 |
|---|---|---|---|---|
| Transmittance | 35% | 38% | 41% | 44% |
| Purity | 59.5% | 63.4% | 64.6% | 66.8% |

The third experimental example EX3 shows a case in which the pattern is not removed, and in the fourth to sixth experimental examples EX4, EX5, and EX6, the degree of pattern removal is gradually increased to evaluate transmittance and purity.

Referring to the third to sixth experimental examples EX3, EX4, EX5, and EX6, when the pattern is removed from the transparent area TA, both the transmittance and purity are improved. The level of improvement in purity is the highest when changing from the third experimental example EX3 to the fourth experimental example EX4, and the purity is improved in the fifth experimental example EX5 and the sixth experimental example EX6.

This means that the pattern affects the refractive index or reflectivity of the removed material. As in the embodiments of the present disclosure, at least the high refractive index inorganic insulating layer causing interlayer interfacial reflection on the encapsulation layer 160 can be removed to improve both transmittance and purity.

A transparent display device according to one embodiment of the present disclosure may comprise a substrate having a plurality of emission areas and a plurality of transparent areas spaced apart from each other, a light-emitting element at the emission areas, an encapsulation layer on the light-emitting elements, a first wiring layer and a second wiring layer disposed on the encapsulation layer and positioned at different layers, a touch buffer layer between the encapsulation layer and the first wiring layer, a touch intermediate insulating layer disposed between the first wiring layer and the second wiring layer, a first protective layer on the second wiring layer, an external light reflection prevention layer disposed on the first protective layer and including a light-shielding layer and a color filter layer and a second protective layer disposed on the external light reflection prevention layer at the plurality of emission areas and on the encapsulation layer at the plurality of transparent areas.

In a transparent display device according to one embodiment of the present disclosure, the second protective layer may be in contact with an upper surface of the encapsulation layer at the plurality of transparent areas.

In a transparent display device according to one embodiment of the present disclosure, each of the touch buffer layer, the touch intermediate insulating layer, and the first protective layer may have a side surface around each of the plurality of transparent regions.

In a transparent display device according to one embodiment of the present disclosure, the touch buffer layer, the touch intermediate insulating layer, and the first protective layer may be disposed to not overlap the plurality of transparent areas.

In a transparent display device according to one embodiment of the present disclosure, the touch buffer layer, the touch intermediate insulating layer, and the first protective layer may be inorganic insulating layers, and the second protective layer may be an organic insulating layer.

In a transparent display device according to one embodiment of the present disclosure, the touch intermediate insulating layer, and the first protective layer may have a refractive index greater than a refractive index of the second protective layer.

In a transparent display device according to one embodiment of the present disclosure, the touch intermediate insulating layer may include a touch contact hole connected to the first wiring layer and the second wiring layer. The touch contact hole may not overlap the plurality of emission areas and the plurality of transparent areas.

In a transparent display device according to one embodiment of the present disclosure, the first wiring layer and the second wiring layer may be disposed to overlap the light-shielding layer.

In a transparent display device according to one embodiment of the present disclosure, the light-emitting element may comprise a plurality of first electrodes spaced apart from each other, a bank at an edge of each of the first electrodes and a spaced area between the first electrodes, an intermediate layer on the first electrodes and the bank and a second electrode on the intermediate layer.

In a transparent display device according to one embodiment of the present disclosure, an edge of the light-shielding layer of the external light reflection prevention layer may be closer to the plurality of transparent regions than an edge of the bank.

In a transparent display device according to one embodiment of the present disclosure, the light-shielding layer of the external light reflection prevention layer may completely overlap the bank and has an area larger than the bank.

In a transparent display device according to one embodiment of the present disclosure, the bank may comprise a light-blocking material or a light-absorbing material.

A transparent display device according to one embodiment of the present disclosure may further comprise a plurality of transistors between the substrate and the plurality of first electrodes, a first planarization layer over the plurality of transistors and a connection electrode connected to one of the plurality of transistors through a contact hole of the first planarization layer.

The first planarization layer may overlap the plurality of transparent areas.

A transparent display device according to one embodiment of the present disclosure may further comprise a second planarization layer between the connection electrode and the plurality of first electrodes.

The connection electrode and one of the plurality of first electrodes may be connected through a contact hole of the second planarization layer.

In a transparent display device according to one embodiment of the present disclosure, each of the plurality of transistors may include an active layer, a gate electrode, a first source-drain electrode, and a second source-drain electrode.

At least one buffer layer may be provided between the substrate and the active layer.

At least one gate insulating layer may be provided between the active layer and the gate electrode.

At least one interlayer insulating layer may be provided between the gate electrode and the first and second source-drain electrodes.

At least one of the at least one buffer layer, the at least one gate insulating layer, and the at least one interlayer insulating layer may be absent at the plurality of transparent areas.

In a transparent display device according to one embodiment of the present disclosure, the first planarization layer may have a lower surface at the plurality of transparent areas than at the plurality of emission areas.

In a transparent display device according to one embodiment of the present disclosure, the first planarization layer may be disposed in contact with vertically continuous side surfaces of at least two layers of the at least one buffer layer, the at least one gate insulating layer, and the at least one interlayer insulating layer around the plurality of transparent areas.

According to the transparent display device of the embodiments of the present disclosure, in a structure in which a color filter array and a touch sensor functional part are further provided on light-emitting elements, the structure of insulating layers within a transparent area can be changed to prevent or minimize or at least reduce interfacial reflection in the transparent area.

The transparent display device of the embodiments of the present disclosure can improve transmittance by changing the configuration within the transparent area.

The transparent display device of the embodiments of the present disclosure can improve purity by changing the configurations of the transparent area and the surrounding area of the transparent area.

The transparent display device of the embodiments of the present disclosure can together improve transmittance and purity of a transparent display device without adding a process, thus has sustainable advantages. Therefore, the transparent display device of the embodiments of the present disclosure can realize ESG (Environmental/Social/Governance) effects.

The transparent display devices of the embodiments of the present disclosure can utilize the same process for components of emission areas and transparent areas without adding a separate layer, reduce the production energy for producing the transparent display device by minimizing the occurrence of defects in the transparent display device, and reduce the use of hazardous production materials or regulated substances, which is advantageous for recycling.

It will be apparent to those skilled in the art that various modifications and variations can be made in the present disclosure without departing from the spirit or scope of the present disclosure. Thus, it is intended that the present disclosure cover the modifications and variations of the present disclosure provided they come within the scope of the appended claims and their equivalents.

What is claimed is:

1. A transparent display device comprising:
a substrate having a plurality of emission areas and a plurality of transparent areas spaced apart from each other;
a light-emitting element at the emission areas;
an encapsulation layer on the light-emitting element;
a first wiring layer and a second wiring layer disposed on the encapsulation layer and positioned at different layers;
a touch buffer layer between the encapsulation layer and the first wiring layer;
a touch intermediate insulating layer disposed between the first wiring layer and the second wiring layer;
a first protective layer on the second wiring layer;
an external light reflection prevention layer disposed on the first protective layer and including a light-shielding layer and a color filter layer; and
a second protective layer disposed on the external light reflection prevention layer at the plurality of emission areas and on the encapsulation layer at the plurality of transparent areas.

2. The transparent display device of claim 1, wherein the second protective layer is in contact with an upper surface of the encapsulation layer at the plurality of transparent areas.

3. The transparent display device of claim 1, wherein each of the touch buffer layer, the touch intermediate insulating layer, and the first protective layer has a side surface around each of the plurality of transparent areas.

4. The transparent display device of claim 1, wherein the touch buffer layer, the touch intermediate insulating layer, and the first protective layer are disposed to not overlap the plurality of transparent areas.

5. The transparent display device of claim 1, wherein the touch buffer layer, the touch intermediate insulating layer, and the first protective layer are inorganic insulating layers, and the second protective layer is an organic insulating layer.

6. The transparent display device of claim 1, wherein each of the touch buffer layer, the touch intermediate insulating layer, and the first protective layer has a refractive index greater than a refractive index of the second protective layer.

7. The transparent display device of claim 1, wherein the touch intermediate insulating layer includes a touch contact hole connected to the first wiring layer and the second wiring layer, and
wherein the touch contact hole does not overlap the plurality of emission areas and the plurality of transparent areas.

8. The transparent display device of claim 1, wherein the first wiring layer and the second wiring layer are disposed to overlap the light-shielding layer.

9. The transparent display device of claim 1, wherein the light-emitting element comprises:
a plurality of first electrodes spaced apart from each other;
a bank at an edge of each of the plurality of first electrodes and a spaced area between the plurality of first electrodes;
an intermediate layer on the plurality of first electrodes and the bank; and
a second electrode on the intermediate layer.

10. The transparent display device of claim 9, wherein an edge of the light-shielding layer of the external light reflection prevention layer is closer to the plurality of transparent areas than an edge of the bank.

11. The transparent display device of claim 9, wherein the light-shielding layer of the external light reflection prevention layer completely overlaps the bank and has an area larger than the bank.

12. The transparent display device of claim 9, wherein the bank comprises a light-blocking material or a light-absorbing material.

13. The transparent display device of claim 9, further comprising:
a plurality of transistors between the substrate and the plurality of first electrodes;
a first planarization layer over the plurality of transistors; and
a connection electrode connected to one of the plurality of transistors through a contact hole of the first planarization layer,
wherein the first planarization layer overlaps the plurality of transparent areas.

14. The transparent display device of claim 13, further comprising a second planarization layer between the connection electrode and the plurality of first electrodes,
wherein the connection electrode and one of the plurality of first electrodes are connected through a contact hole of the second planarization layer.

15. The transparent display device of claim 13, wherein each of the plurality of transistors includes an active layer, a gate electrode, a first source-drain electrode, and a second source-drain electrode,
wherein at least one buffer layer is provided between the substrate and the active layer,
at least one gate insulating layer is provided between the active layer and the gate electrode,
at least one interlayer insulating layer is provided between the gate electrode and the first and second source-drain electrodes, and
at least one of the at least one buffer layer, the at least one gate insulating layer, and the at least one interlayer insulating layer is absent at the plurality of transparent areas.

16. The transparent display device of claim 13, wherein the first planarization layer has a lower surface at the plurality of transparent areas than at the plurality of emission areas.

17. The transparent display device of claim 15, wherein the first planarization layer is disposed in contact with vertically continuous side surfaces of at least two layers of the at least one buffer layer, the at least one gate insulating layer, and the at least one interlayer insulating layer around the plurality of transparent areas.
